(19) United States
(12) Patent Application Publication
(10) Pub. No.: US 2023/0380244 A1
(43) Pub. Date: Nov. 23, 2023

(54) DISPLAY APPARATUS AND METHOD OF MANUFACTURING DISPLAY APPARATUS

(71) Applicant: SAMSUNG DISPLAY CO., LTD., YONGIN-SI (KR)

(72) Inventors: Jaesul AN, YONGIN-SI (KR); Byunghoon KIM, YONGIN-SI (KR); Youngdo KIM, YONGIN-SI (KR); Hyukhwan KIM, YONGIN-SI (KR); Aely OH, YONGIN-SI (KR); Hyunseok OH, YONGIN-SI (KR); Kangwoo LEE, YONGIN-SI (KR)

(21) Appl. No.: 18/131,480

(22) Filed: Apr. 6, 2023

(30) Foreign Application Priority Data
May 17, 2022 (KR) 10-2022-0060443
Jun. 16, 2022 (KR) 10-2022-0073790

(51) Int. Cl. H10K 59/80; H10K 59/12; H10K 59/131; H10K 71/20

(52) U.S. Cl. CPC H10K 59/873; H10K 59/1201; H10K 59/131; H10K 71/231; H10K 2102/311

(57) ABSTRACT

A display apparatus includes a substrate including a first area, a second area, and a third area. The first area faces a first direction. The second area extends from the first area and faces a second direction different from the first direction. The third area is disposed between the first area and the second area. A display element is arranged in the first area. A bending-protecting layer is arranged in the third area and is disposed outside of the first area. A thickness of the substrate in the third area is less than a thickness of the substrate in the first area.

### CROSS-REFERENCE TO RELATED APPLICATIONS

This application claims priority under 35 U.S.C. § 119 to Korean Patent Application No. 10-2022-0060443, filed on May 17, 2022 in the Korean Intellectual Property Office, and Korean Patent Application No. 10-2022-0073790, filed on Jun. 16, 2022 in the Korean Intellectual Property Office, the disclosures of which are incorporated by reference in their entireties herein.

### 1. TECHNICAL FIELD

One or more embodiments relate to a display apparatus and a method of manufacturing a display apparatus.

### 2. DISCUSSION OF RELATED ART

A display apparatus is an electronic device that displays images. The display apparatus may include a substrate divided into a display area and a non-display area. A plurality of pixel areas are defined in the display area. In addition, a thin-film transistor and a pixel electrode are provided in the display area to correspond to each of pixel areas. The pixel electrode is electrically connected to the thin-film transistor. Various conductive layers such as wirings and the like are positioned in the non-display area and are configured to transfer electrical signals to the display area.

Display apparatuses are being developed to be deformable, such as being bendable, foldable, rollable, etc. For example, in a deformable display apparatus, visibility at various angles may be increased or the area of the non-display area may be reduced by bending or folding at least a portion of the display apparatus.

### SUMMARY

One or more embodiments of the present disclosure include a display apparatus in which cracks in a bent area are prevented and a dead space due to the bent area is reduced, and a method of manufacturing a display apparatus.

Additional aspects will be set forth in part in the description which follows and, in part, will be apparent from the description, or may be learned by practice of the presented embodiments of the disclosure.

According to an embodiment of the present disclosure, a display apparatus includes a substrate including a first area, a second area, and a third area. The first area faces a first direction. The second area extends from the first area and faces a second direction different from the first direction. The third area is disposed between the first area and the second area.

A display element is arranged solely in the first area. A bending-protecting layer is arranged in the third area and is solely disposed outside of the first area. A thickness of the substrate in the third area is less than a thickness of the substrate in the first area.

In an embodiment, an inner radius of the third area may be in a range of about 0.17 mm to about 0.19 mm.

In an embodiment, a thickness of the bending-protecting layer may be in a range of about 0.04 mm to about 0.1 mm.

In an embodiment, the display apparatus may further include a pad portion arranged in the second area. A connection wiring is arranged in the third area. The connection wiring electrically connects the display element to the pad portion.

In an embodiment, a stress neutral plane in the third area may be arranged between a surface of the substrate and the connection wiring.

In an embodiment, the substrate may include a first base layer and a second base layer stacked on the first base layer.

In an embodiment, a thickness of the first base layer in the third area may be less than a thickness of the first base layer in the first area.

In an embodiment, the thickness of the first base layer in the third area may be less than a thickness of the first base layer in the second area.

In an embodiment, a relational equation between a modulus of the bending-protecting layer and a thickness of the first base layer in the third area is equal to y=62x-70 in which x is the thickness of the first base layer in the third area and y is the modulus of the bending-protecting layer.

In an embodiment, a modulus of the bending-protecting layer may be greater than 62x-70 and less than 1.4*(62x-70).

In an embodiment, the display apparatus may further include a barrier layer disposed between the first base layer and the second base layer.

According to an embodiment of the present disclosure, a method of manufacturing a display apparatus includes preparing a substrate including a first area, a second area, and a third area. The second area is spaced apart from the first area. The third area is disposed between the first area and the second area. A display element is formed solely in the first area. A thin-film encapsulation layer is formed that covers the display element. A thickness of the substrate in the third area is reduced to be less than a thickness of the substrate in the first area. A bending-protecting layer is formed in the third area. The bending-protecting layer is solely disposed outside of the first area. The third area is bent so that the first area faces a first direction that is different from a second direction that the second area faces.

In an embodiment, the bending of the third area may include bending the third area such that an inner radius of the third area is in a range of about 0.17 mm to about 0.19 mm.

In an embodiment, a thickness of the bending-protecting layer may be in a range of about 0.04 mm to about 0.1 mm.

In an embodiment, the method may further include, after the forming of the thin-film encapsulation layer and before the reducing of the thickness of the third area, forming a pad portion in the second area and forming a connection wiring in the third area. The connection wiring electrically connects the display element to the pad portion.

In an embodiment, the reducing of the thickness of the third area may include reducing the thickness of the third area such that a stress neutral plane in the third area is formed between a surface of the substrate and the connection wiring.

In an embodiment, the reducing of the thickness of the third area may include etching the substrate by using a laser beam or plasma.

In an embodiment, the substrate may be formed by stacking a first base layer and a second base layer on the first base layer.

In an embodiment, a thickness of the first base layer in the third area may be less than a thickness of the first base layer in the first area.

In an embodiment, the thickness of the first base layer in the third area may be less than a thickness of the first base layer in the second area.

In an embodiment, a relational equation between a modulus of the bending-protecting layer and a thickness of the first base layer in the third area is equal to y=62x-70 in which x is the thickness of the first base layer in the third area and y is the modulus of the bending-protecting layer.

In an embodiment, a modulus of the bending-protecting layer may be greater than 62x-70 and less than 1.4*(62x-70).

In an embodiment, the method may further include forming a barrier layer between the first base layer and the second base layer.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a plan view of a display apparatus according to an embodiment of the present disclosure;

FIG. 2 is a perspective view of a display apparatus according to an embodiment of the present disclosure;

FIG. 3 is a plan view of a display apparatus according to an embodiment of the present disclosure;

FIG. 4 is an equivalent circuit diagram of a pixel of a display apparatus according to an embodiment of the present disclosure;

FIG. 5 is a cross-sectional view of a portion of the display apparatus, taken along line I-T of FIG. 3 according to an embodiment of the present disclosure;

FIG. 6 is a cross-sectional view of a portion of a display apparatus according to an embodiment of the present disclosure;

FIG. 7 is a cross-sectional view of a portion of a display apparatus according to an embodiment of the present disclosure;

FIG. 8 is a cross-sectional view of a third area of the display apparatus shown in FIG. 7 according to an embodiment of the present disclosure; and

FIG. 9 is a flowchart showing a method of manufacturing a display apparatus according to an embodiment of the present disclosure.

### DETAILED DESCRIPTION OF EMBODIMENTS

Reference will now be made in detail to embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, non-limiting embodiments are merely described below, by referring to the figures, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present disclosure allows for various changes and numerous embodiments, certain non-limiting embodiments will be illustrated in the drawings and described in the written description. Effects and features of the disclosure, and methods for achieving them will be clarified with reference to embodiments described below in detail with reference to the drawings. However, embodiments of the present disclosure are not necessarily limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region or component. That is, for example, intervening layers, regions, or components may be present. When a layer, region, or component is referred to as being “directly on” another layer, region or component, no intervening layers, regions, or components may be present.

Sizes of elements in the drawings may be exaggerated or reduced for convenience of explanation. As an example, the size and thickness of each element shown in the drawings may be arbitrarily represented for convenience of description, and thus, the present disclosure are not necessarily limited thereto.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component interposed therebetween.

The x-axis, the y-axis and the z-axis are not necessarily limited to three axes of the rectangular coordinate system, and may be interpreted in a broader sense. For example, the x-axis, the y-axis, and the z-axis may be perpendicular to one another, or may represent different directions that are not perpendicular to one another.

A display apparatus is an apparatus configured to display images and may include liquid crystal displays, electrophoretic displays, organic light-emitting displays, inorganic light-emitting displays, field emission displays, surface-conduction electron-emitter displays, plasma displays, cathode ray displays, and the like.

Hereinafter, though an organic light-emitting display apparatus is described as an example of the display apparatus according to an embodiment, the display apparatus according to an embodiment is not necessarily limited thereto but the various types of display apparatuses may be used.

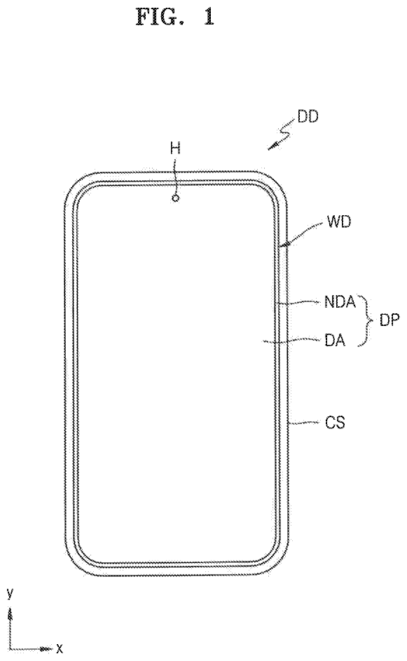

FIG. 1 is a schematic plan view of a display apparatus DD according to an embodiment of the present disclosure.

Referring to FIG. 1, the display apparatus DD may include a display panel DP configured to display images, and a window WD and a case CS configured to protect the display panel DP.

The display panel DP may be configured to display various different visual information, for example, text, videos, photos, two-dimensional and/or three-dimensional images, and the like. Hereinafter, the various visual information is denoted by “images”. In an embodiment, the kind, structure and/or shape of the display panel DP are not necessarily limited to that shown in the drawings. As an example, the display panel DP may include self-luminous display panels such as organic light-emitting display (OLED) panels, and non-emission display panels such as liquid crystal display (LCD) panels, electro-phoretic display (EPD) panels, and electro-wetting display (EWD) panels. In an embodiment in which a non-emission display panel is used as the display panel DP of the display apparatus DD, the display apparatus DD may include a light source portion (e.g., a backlight unit) configured to supply light to the display panel DP.

In an embodiment, the display panel DP may include a display area DA and a non-display area NDA around the display area DA. The display area DA may include a plurality of pixels configured to display images. Though a light-transmissive hole region H (e.g., a non-pixel area in which pixels are not arranged, or a low-resolution region in which pixels are arranged at low resolution) corresponding to a camera and the like may be formed in the display area, embodiments of the present disclosure are not necessarily limited thereto. The non-display area NDA may be arranged on at least one side of the display area DA to surround the display area DA partially or entirely. Wirings, pads, and/or at least one driving circuit configured to drive the pixels in the display area DA may be arranged in the non-display area NDA.

The window WD and the case CS may be coupled to the display panel DP and may protect the display panel DP from impacts applied from the outside. As an example, in an embodiment the window WD may be located on the front surface of the display apparatus DD to be disposed on the upper portion of the display panel DP, and the case CS may be located on the lateral surface and/or the rear surface of the display apparatus DD to surround the lateral surface and/or the rear surface of the display panel DP.

The display apparatus DD may include at least one kind of sensor to provide various functions. As an example, the display apparatus DD may include a fingerprint sensor configured to provide a biometric information authentication function. In addition, the display apparatus DD may further include a sensor configured to provide a touch input function.

As an example, the display apparatus DD may include the fingerprint sensor provided to the rear surface of the display panel DP to overlap a region of the display area DA. However, the position of the fingerprint sensor may be variously changed. As an example, the fingerprint sensor may be provided to overlap the non-display area NDA.

The display apparatus DD may have various shapes. As an example, the display apparatus DD may have a rectangular shape in which a horizontal length (e.g., a width) in an x direction is less than a vertical length in a y direction. However, embodiments of the present disclosure are not necessarily thereto. As an example, in an embodiment, the display apparatus DD may have a rectangular shape in which a horizontal length is greater than a vertical length, or a square shape in which a horizontal length is substantially the same as a vertical length. However, the display apparatus DD may have various shapes. As an example, the display apparatus DD may have various polygonal shapes, circular shapes, elliptical shapes, and/or combinations thereof. In addition, the display apparatus DD may have an angled corner or a round corner.

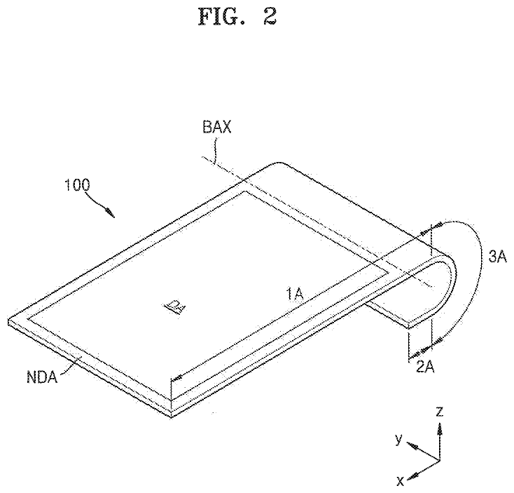

FIG. 2 is a schematic perspective view of the display apparatus DD according to an embodiment.

Referring to FIG. 2, a portion of a substrate 100, which is a portion of the display apparatus DD, may be bent, and the display apparatus DD may have a shape in which the portion of the display apparatus DD is bent like the substrate 100.

The substrate 100 may include a first area 1A, a second area 2A, and a third area 3A. In an embodiment, the first area 1A faces a first direction, the second area 2A extends from the first area 1A and faces a second direction different from the first direction, and the third area 3A is located between the first area 1A and the second area 2A. As shown in FIG. 2, in an embodiment in which the first direction that the first area 1A faces is a +z direction, the second direction which the second area 2A faces may be a −z direction. The first area 1A and the second area 2A may respectively face directions opposite to each other. For example, one surface of the first area 1A and one surface of the second area 2A may be positioned parallel to each other in an unfolded state and may be provided in a folded state to face each other. However, embodiments of the present disclosure are not necessarily limited thereto and may include embodiments in which the first area 1A and the second area 2A do not face each other and have various different angles with respect to each other.

The third area 3A may be located between the first area 1A and the second area 2A. As shown in FIG. 2, as an example, the third area 3A may be bent around a bending axis BAX extending in the y direction perpendicular to the first direction (the z direction). Though it is shown in FIG. 2 that the substrate 100 is bent with the same curvature radius with respect to the bending axis BAX, embodiments of the present disclosure are not necessarily limited thereto. The substrate 100 may be bent around the bending axis BAX such that a curvature radius is not constant.

In an embodiment, the third area 3A may be arranged continuous with the first area 1A, and the second area 2A may be arranged continuous with the third area 3A. Though the third area 3A may be integrally formed with the first area 1A to be continuous with the first area 1A, embodiments of the present disclosure are not necessarily limited thereto.

In an embodiment, the first area 1A may be provided in at least a portion of the display area DA and/or the non-display area NDA. The third area 3A may be provided in the non-display area NDA. As an example, as shown in FIG. 2, the non-display area NDA may include a protrusion area protruding from a portion of the non-display area NDA in at least one direction (e.g., a −x direction), and be folded or bent in the protrusion area. As an example, the first area 1A may be provided in the display area DA and/or the non-display area NDA around the display area DA. The third area 3A and the second area 2A may be provided in the protrusion area of the non-display area NDA.

The protrusion area of the non-display area NDA may be folded (or bent or rolled) afterward along a folding line, and because the protrusion area of the non-display area NDA is folded (or bent), the width of a bezel may be reduced.

In an embodiment, the substrate 100 may include various flexible or bendable materials. The substrate 100 may include, for example, a polymer resin such as polyethersulfone (PES), polyacrylate (PAR), polyetherimide (PEI), polyethylene naphthalate (PEN), polyphenylene sulfide (PPS), polyarylate, polyimide (PI), or cellulose acetate propionate (CAP). However, embodiments of the present disclosure are not necessarily limited thereto.

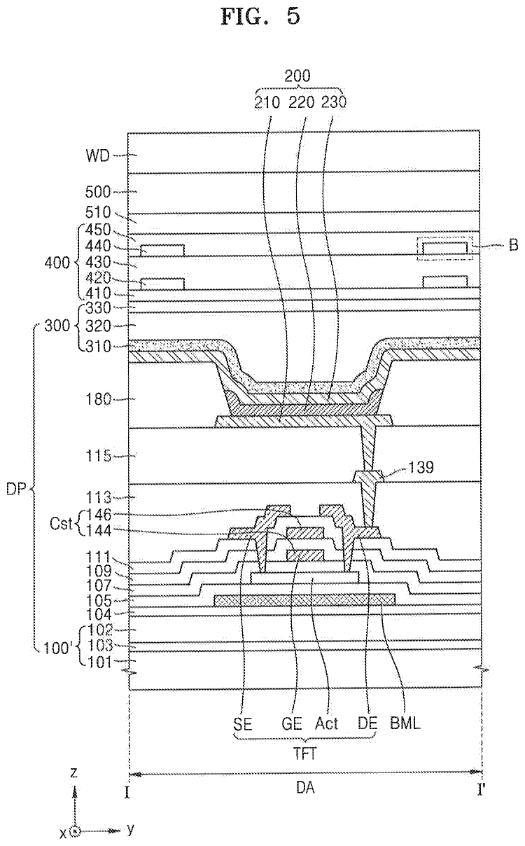

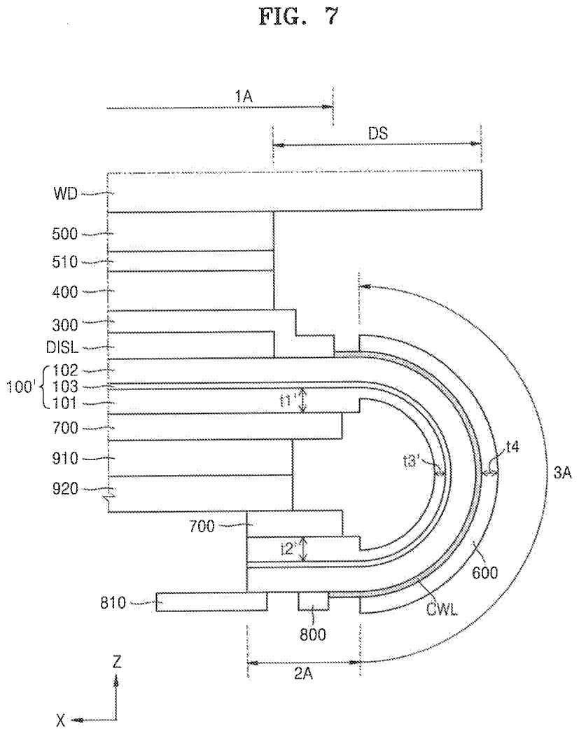

The substrate 100 may have a single-layered structure or a multi-layered structure of the above materials, and may further include an inorganic layer in an embodiment having the multi-layered structure. A substrate 100′ of a multi-layered structure according to an embodiment is described below with reference to FIGS. 5 and 7.

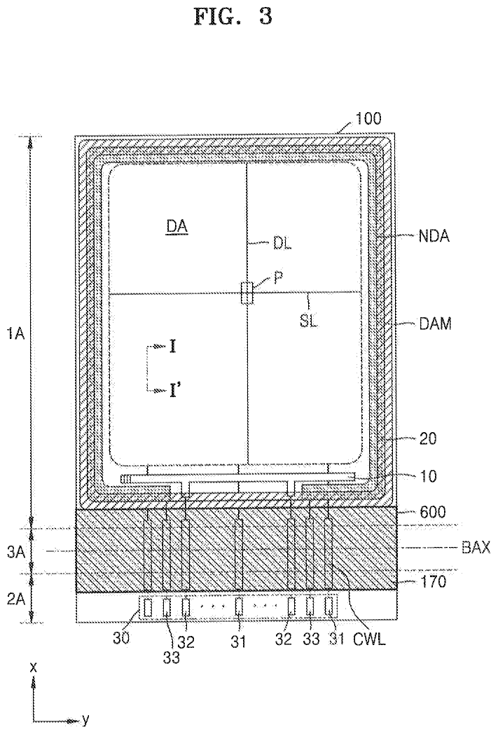

FIG. 3 is a schematic plan view of the display apparatus DD according to an embodiment. For convenience of illustration, FIG. 3 shows the display apparatus DD that is not bent.

As described above, the first area 1A of the substrate 100 may include the display area DA and the non-display area NDA near the display area DA.

A plurality of pixels P may be arranged in the display area DA of the substrate 100 and configured to display images. A thin-film transistor, a display element such as an organic light-emitting element, a capacitor, and the like may be provided in the display area DA.

In the display area DA, the pixel P is formed by electrical coupling of the thin-film transistor, the capacitor, the organic light-emitting element, and the like. The thin-film transistor is connected to a scan line SL configured to transfer scan signals, a data line DL configured to transfer data signals, and a driving power line 10 configured to transfer power. The display area DA may be configured to display images. The pixel P may be configured to emit light at a brightness corresponding to a driving current flowing through the organic light-emitting element in response to a data signal according to a driving power and a common power supplied to the pixel P. In an embodiment, the signal lines may be connected to a controller connected to a pad portion 30 through a connection wiring CWL of the non-display area NDA. The pixel P may be provided in plurality, and the plurality of pixels P may be arranged in various configurations such as a stripe configuration, a pentile configuration PenTile™, and the like.

The pad portion 30, a driving power line 10, a common power line 20, and the connection wirings CWL may be arranged in the non-display area NDA. In addition, in an embodiment a gate driver, a data driver, and the like may be further arranged in the non-display area NDA.

The pad portion 30 may be arranged in one end of the non-display area NDA and may include a plurality of terminals, such as a terminal 31, a driving terminal 32, and a common terminal 33. The pad portion 30 may be exposed by not being covered by an insulating layer and electrically connected to the controller such as a flexible printed circuit board, a driver integrated circuit (IC), or the like. The controller may be configured to provide data signals, scan signals, a driving voltage, a common voltage, and the like.

The driving power line 10 may be connected to the controller through the driving terminal 32 and configured to provide the driving voltage to the pixels P. The driving voltage is provided from the controller. The driving power line 10 may be arranged in the non-display area NDA to correspond to one side of the display area DA. Wirings configured to supply data signals or scan signals to the display area DA may cross the driving voltage line 10. In this embodiment, the connection wirings CWL may be connected to the wirings through contact holes.

The common power line 20 may be connected to the controller through the common terminal 33 and configured to provide the common voltage to the pixels P. The common voltage is provided from the controller. The common power line 20 may be arranged in the non-display area NDA to surround at least a portion of the display area DA. In an embodiment, the common power line 20 may extend along an entirety of the sides except for a side of the display area DA adjacent to the driving power line 10.

At least one connection wiring CWL may be arranged in the third area 3A. In this embodiment, the connection wiring CWL may extend to the second area 2A through the first area 1A and the third area 3A. The connection wiring CWL may extend to cross the bending axis BAX. As an example, though the connection wiring CWL may extend perpendicularly with respect to the bending axis BAX, embodiments of the present disclosure are not necessarily limited thereto. For example, the connection wiring CWL may extend obliquely with respect to the bending axis BAX at a preset angle. However, various modifications may be made. In addition, the connection wiring CWL may have a curved shape, a zigzag shape, and the like, as opposed to a straight line shape. However, the connection wirings CWL may have various shapes. The connection wirings CWL may be connected to wirings disposed on different layers through contact holes.

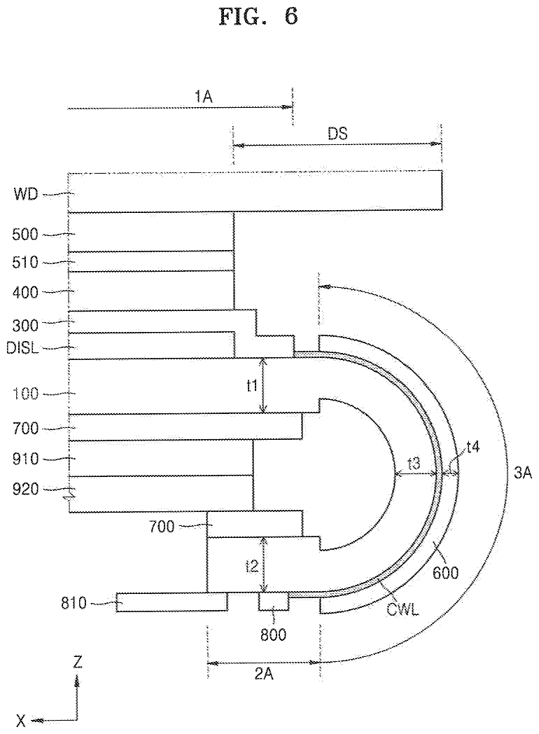

A bending-protecting layer 600 may be disposed on the connection wiring CWL in the third area 3A. The bending-protecting layer 600 may be configured to protect cracks of the connection wiring CWL in the third area 3A. This is described below with reference to FIG. 6. In an embodiment, the bending-protecting layer 600 may be solely disposed outside of the first area 1A.

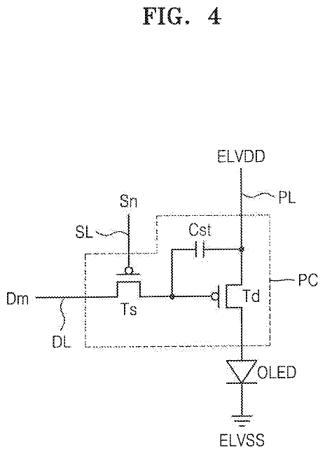

FIG. 4 is an equivalent circuit diagram of the pixel P of the display apparatus DD according to an embodiment.

Referring to FIG. 4, each pixel P may include a pixel circuit PC and an organic light-emitting diode OLED connected to the pixel circuit PC. The pixel circuit PC is connected to the scan line SL and the data line DL.

The pixel circuit PC may include a driving thin-film transistor Td, a switching thin-film transistor Ts, and a storage capacitor Cst. The switching thin-film transistor Ts may be connected to the scan line SL and the data line DL, and configured to transfer a data signal Dm to the driving thin-film transistor Td according to a scan signal Sn. The data signal Dm is input through the data line DL, and the scan signal Sn is input through the scan line SL.

The storage capacitor Cst may be connected to the switching thin-film transistor Ts and a driving voltage line PL and configured to store a voltage corresponding to a difference between a voltage transferred from the switching thin-film transistor Ts and a first power voltage ELVDD supplied to the driving voltage line PL.

The driving thin-film transistor Td may be connected to the driving voltage line PL and the storage capacitor Cst and configured to control the driving current according to the voltage stored in the storage capacitor Cst. The driving current flows from the driving voltage line PL to the organic light-emitting diode OLED. The organic light-emitting diode OLED may be configured to emit light having a preset brightness corresponding to the driving current.

Though it is described with reference to FIG. 4 that the pixel circuit PC includes two thin-film transistors and one storage capacitor, embodiments of the present disclosure are not necessarily limited thereto. For example, in an embodiment, the pixel circuit PC may include seven thin-film transistors and one storage capacitor. In an embodiment, the pixel circuit PC may include two or more storage capacitors.

FIG. 5 is a cross-sectional view of a portion of the display apparatus DD, taken along line I-I′ of FIG. 3.

Referring to FIG. 5, a thin-film transistor TFT and a display element 200 may be disposed over the substrate 100′.

The substrate 100′ may include various flexible, bendable, or rollable materials. As an example, in an embodiment the first substrate 100′ may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. In an embodiment, the substrate 100′ may include a base layer 101 and a second base layer 102 disposed on the base layer 101. A second barrier layer 103 may be disposed between the first base layer 101 and the second base layer 102 (e.g., in the z direction). However, embodiments of the present disclosure are not necessarily limited thereto and the substrate 100′ may include a single layer in which the first, second, and third areas 1A, 2A, and 3A include the same material.

A first barrier layer 104 may be disposed on the substrate 100′. In an embodiment, the first barrier layer 104 may include at least one inorganic insulating material among silicon oxide (SiO₂), silicon nitride (SiNs), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂). The first barrier layer 104 may include a single layer or a multi-layer including the inorganic insulating material. However, embodiments of the present disclosure are not necessarily limited thereto. For example, in an embodiment, the first barrier layer 104 may be omitted.

A buffer layer 105 may be disposed on the first barrier layer 104. The buffer layer 105 may be disposed on the substrate 100′, may reduce or block penetration of foreign materials, moisture, or external air from below the substrate 100′, and provide a flat surface on the substrate 100′ (e.g., planarize the substrate 100′). In an embodiment, the buffer layer 105 may include an inorganic material, an organic material, or an organic/inorganic composite material, and include a single layer or a multi-layer including an inorganic material and an organic material, the inorganic material including oxide or nitride.

A bottom metal layer BML may be disposed between the first barrier layer 104 and the buffer layer 105. The bottom metal layer BML may overlap the thin-film transistor TFT thereover (e.g., in the −z direction).

The thin-film transistor TFT may be disposed on the buffer layer 105. The thin-film transistor TFT may include a semiconductor layer Act, a gate electrode GE, a source electrode SE, and a drain electrode DE. The gate electrode GE overlaps the semiconductor layer Act, and the source electrode SE and the drain electrode DE are electrically connected to the semiconductor layer Act. The thin-film transistor TFT may be connected to the display element 200 and may drive the display element 200.

The semiconductor layer Act may be disposed on the buffer layer 105 and may include a channel region, a source region, and a drain region. The channel region overlaps the gate electrode GE, and the source region and the drain region are respectively disposed on two opposite sides of the channel region (e.g., in the y, −y directions) and includes impurities of higher concentration than the channel region. In an embodiment, the impurities may include N-type impurities or P-type impurities. The source region and the drain region may be respectively electrically connected to the source electrode SE and the drain electrode DE.

The semiconductor layer Act may include an oxide semiconductor and/or a silicon semiconductor. In an embodiment in which the semiconductor layer Act includes an oxide semiconductor, the semiconductor layer Act may include, for example, an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). As an example, the semiconductor layer Act may include ITZO(InSnZnO), IGZO(InGaZnO), or the like. In an embodiment in which the semiconductor layer Act includes a silicon semiconductor, the semiconductor layer Act may include, for example, amorphous silicon (a-Si) or a low-temperature polycrystalline silicon formed by crystalizing amorphous silicon (a-Si).

A first insulating layer 107 may be disposed on the semiconductor layer Act. In an embodiment, the first insulating layer 107 may include at least one inorganic insulating material among silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂). The first insulating layer 107 may include a single layer or a multi-layer including the inorganic insulating material.

The gate electrode GE may be disposed on the first insulating layer 107. In an embodiment, the gate electrode GE may include at least one metal among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and include a single layer or a multi-layer including the above metals. The gate electrode GE may be connected to a gate line configured to apply electrical signals to the gate electrode GE.

A second insulating layer 109 may be disposed on the gate electrode GE. In an embodiment, the second insulating layer 109 may include at least one inorganic insulating material among silicon oxide (SiO₂), silicon nitride (SiN), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂). The second insulating layer 109 may include a single layer or a multi-layer including the inorganic insulating materials.

The storage capacitor Cst may be disposed on the first insulating layer 107. The storage capacitor Cst may include a lower electrode 144 and an upper electrode 146 overlapping the lower electrode 144. The lower electrode 144 of the storage capacitor Cst may overlap the upper electrode 146 (e.g., in the −z direction) with the second insulating layer 109 therebetween.

The lower electrode 144 of the storage capacitor Cst may overlap the gate electrode GE of the thin-film transistor TFT. In an embodiment, the lower electrode 144 of the storage capacitor Cst may be integrally formed with the gate electrode GE of the thin-film transistor TFT. However, embodiments of the present disclosure are not necessarily limited thereto. For example, in an embodiment, the storage capacitor Cst may not overlap the thin-film transistor TFT. The lower electrode 144 of the storage capacitor Cst may be an independent element separate from the gate electrode GE of the thin-film transistor TFT.

In an embodiment, the upper electrode 146 of the storage capacitor Cst may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials.

A third insulating layer 111 may be disposed on the upper electrode 146 of the storage capacitor Cst. In an embodiment, the third insulating layer 111 may include at least one inorganic insulating material among silicon oxide (SiO₂), silicon nitride (SiN), silicon oxynitride (SiOₓN_{y}), aluminum oxide (Al₂O₃), titanium oxide (TiO₂), tantalum oxide (Ta₂O), hafnium oxide (HfO₂), or zinc oxide (ZnO₂). The third insulating layer 111 may include a single layer or a multi-layer including the inorganic insulating material.

The source electrode SE and the drain electrode DE may be disposed on the third insulating layer 111. In an embodiment, the source electrode SE and the drain electrode DE may each include a conductive material including molybdenum (Mo), aluminum (Al), copper (Cu), and titanium (Ti) and include a single layer or a multi-layer including the above materials. The source electrode SE and the drain electrode DE may have a multi-layered structure of Ti/Al/Ti.

A first planarization layer 113 may be disposed on the source electrode SE and the drain electrode DE. The first planarization layer 113 may include an organic material or an inorganic material and included a single layer or a multi-layer. In an embodiment, the first planarization layer 113 may include a general-purpose polymer such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. The first planarization layer 113 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). In an embodiment, after the first planarization layer 113 is formed, chemical mechanical polishing may be performed to provide a flat upper surface.

A connection electrode 139 may be disposed on the first planarization layer 113. In an embodiment, the connection electrode 139 may include at least one of aluminum (Al), copper (Cu), titanium (Ti) and the like and include a single layer or a multi-layer. For example, the connection electrode 139 may have a multi-layered structure of Ti/Al/Ti.

A second planarization layer 115 may be disposed on the connection electrode 139. The second planarization layer 115 may include an organic material or an inorganic material and included a single layer or a multi-layer. In an embodiment, the second planarization layer 115 may include the same material as a material of the first planarization layer 113. However, embodiments of the present disclosure are not necessarily limited thereto. For example, the second planarization layer 115 may include a material different from a material of the first planarization layer 113.

The display element 200 may be disposed on the second planarization layer 115. In an embodiment, the display element 200 includes a pixel electrode 210, an intermediate layer 220, and an opposite electrode 230. As an example, the display element 200 including the pixel electrode 210, the intermediate layer 220, and the opposite electrode 230 may be an organic light-emitting element.

The pixel electrode 210 may be electrically connected to the connection electrode 139 through a contact hole passing through the second planarization layer 115, and the connection electrode 139 may be electrically connected to the source electrode SE or the drain electrode DE of the thin-film transistor TFT through a contact hole passing through the first planarization layer 113. Accordingly, the display element 200 may be electrically connected to the thin-film transistor TFT.

The pixel electrode 210 may be disposed on the second planarization layer 115. The pixel electrode 210 may be a (semi) light-transmissive electrode or a reflective electrode. The pixel electrode 210 may include a reflective layer and a transparent or semi-transparent electrode layer formed on the reflective layer. In an embodiment, the reflective layer includes at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and a compound thereof. The transparent or semi-transparent electrode layer may include at least one of indium tin oxide, indium zinc oxide, zinc oxide, indium oxide, indium gallium oxide, and aluminum zinc oxide. The pixel electrode 210 may have a stack structure of ITO/Ag/ITO.

A pixel-defining layer 180 may be disposed on the second planarization layer 115 and may include an opening exposing at least a portion of the pixel electrode 210. A region exposed by the opening of the pixel-defining layer 180 may be defined as an emission area. The periphery of the emission areas is a non-emission area, and the non-emission area may surround the emission areas. For example, the display area DA may include the plurality of emission areas and the non-emission area surrounding the plurality of emission areas. The pixel-defining layer 180 may prevent arcs and the like from occurring at the edges of the pixel electrode 210 by increasing a distance between the pixel electrode 210 and the opposite electrode 230 over the pixel electrode 210. In an embodiment, the pixel-defining layer 180 may include an organic insulating material such as polyimide, polyamide, an acryl resin, benzocyclobutene, hexamethyldisiloxane (HMIDSO), and a phenolic resin, and be formed by spin coating and the like.

The intermediate layer 220 may be disposed on at least a portion of the pixel electrode 210 exposed by the pixel-defining layer 180. The intermediate layer 220 may include an emission layer. In an embodiment, a first functional layer and/or a second functional layer may be selectively disposed under and on the emission layer.

In an embodiment, the emission layer of the intermediate layer 220 may be disposed on at least a portion of the pixel electrode 210 exposed by the pixel-defining layer 180.

In an embodiment, the first functional layer may include a hole injection layer and/or a hole transport layer, and the second functional layer may include an electron transport layer and/or an electron injection layer.

The emission layer may include an organic material including a fluorescent or phosphorous material emitting red, green, blue, or white light. However, embodiments of the present disclosure are not necessarily limited thereto and the colors of the emission layer may vary. The emission layer may include a low molecular weight organic material or a polymer organic material.

In an embodiment in which the emission layer includes a low molecular weight organic material, the intermediate layer 220 may have a structure in which a hole injection layer, a hole transport layer, an emission layer, an electron transport layer, an electron injection layer, etc. are stacked in a single or composite configuration. In an embodiment, the intermediate layer 220 may include, as a low molecular weight organic material, various organic materials such as copper phthalocyanine (CuPc), N, N′-Di (naphthalene-1-yl)-N, N′-diphenyl-benzidine (NPB), and tris-8-hydroxyquinoline aluminum (Alq3). These layers may be formed by vacuum deposition.

In an embodiment in which the emission layer include a polymer organic material, the intermediate layer 220 may generally have a structure including the hole transport layer and the emission layer. For example, the hole transport layer may include poly (3, 4-ethylenedioxythiophene) (PEDOT), and the emission layer may include a polymer material such as a polyphenylene vinylene (PPV)-based material and a polyfluorene-based material. The emission layer may be formed by screen printing, inkjet printing, laser induced thermal imaging (LITI), or the like.

The opposite electrode 230 may be disposed on the intermediate layer 220. The opposite electrode 230 is disposed on the intermediate layer 220 and may be disposed to cover the intermediate layer 220 entirely. In an embodiment, the opposite electrode 230 is arranged in the display area DA and may be arranged to cover the display area DA entirely. For example, the opposite electrode 230 may be formed as one body over the display panel DP entirely to cover the plurality of pixels arranged in the display area DA by using an open mask. However, embodiments of the present disclosure are not necessarily limited thereto.

The opposite electrode 230 may include a conductive material having a low work function. As an example, in an embodiment the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. Alternatively, the opposite electrode 230 may further include a layer on the (semi) transparent layer, the layer including ITO, IZO, ZnO, or In₂O₃.

A thin-film encapsulation layer 300 may be disposed on the display element 200, for example, the opposite electrode 230. The thin-film encapsulation layer 300 may include at least one inorganic encapsulation layer and at least one organic encapsulation layer. The thin-film encapsulation layer 300 may prevent oxygen or moisture from penetrating the intermediate layer 220 including the emission layer and the opposite electrode 230. As an example, in an embodiment the thin-film encapsulation layer 300 may include a first inorganic encapsulation layer 310, an organic encapsulation layer 320, and a second inorganic encapsulation layer 330. The first inorganic encapsulation layer 310 is disposed on the opposite electrode 230, the organic encapsulation layer 320 is disposed on the first inorganic encapsulation layer 310, and the second inorganic encapsulation layer 330 is disposed on the organic encapsulation layer 320. In an embodiment, the first inorganic encapsulation layer 310 and the second inorganic encapsulation layer 330 may each include silicon nitride (SiNₓ), silicon oxynitride (SiOₓN_{y}), silicon oxide (SiO₂), titanium oxide (TiO₂), or aluminum oxide (Al₂O₃). The organic encapsulation layer 320 may include acrylic resin, epoxy resin, phenolic resin, polyamide resin, or polyimide resin.

The thin-film encapsulation layer 300 may extend to the outside of the display area DA to the non-display area NDA (FIG. 1). The first inorganic encapsulation layer 310 may directly contact the second inorganic encapsulation layer 330 outside of the display area DA, such as in the non-display area NDA.

A sensor layer 400 may be disposed on the thin-film encapsulation layer 300. In an embodiment, the sensor layer 400 may include a first sensor insulating layer 410, a second sensor insulating layer 430, and a third sensor insulating layer 450. In addition, the sensor layer 400 may include a first sensor electrode 420 and a second sensor electrode 440. The first sensor electrode 420 is between the first sensor insulating layer 410 and the second sensor insulating layer 430, and the second sensor electrode 440 is between the second sensor insulating layer 430 and the third sensor insulating layer 450. The first sensor electrode 420 and the second sensor electrode 440 may include driving electrodes and sensing electrodes. In an embodiment, the first sensor electrode 420 may be electrically connected to the second sensor electrode 440 through a contact hole defined in the second sensor insulating layer 430.

In an embodiment, the first sensor insulating layer 410 may include at least one inorganic insulating material among silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The first sensor insulating layer 410 may have a single-layered structure or a multi-layered structure. However, embodiments of the present disclosure are not necessarily limited thereto. For example, in an embodiment, the first sensor insulating layer 410 may include at least one of an acryl-based resin, methacryl-based resin, polyisoprene, vinyl-based resin, epoxy-based resin, urethane-based resin, cellulose-based resin, siloxane-based resin, polyimide-based resin, polyamide-based resin, and perylene-based resin. In some embodiments, the first sensor insulating layer 410 may be omitted.

In an embodiment, the second sensor insulating layer 430 may include at least one inorganic insulating material among silicon oxide (SiO₂), silicon nitride (SiN), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The first sensor insulating layer 410 may have a single-layered structure or a multi-layered structure. However, embodiments of the present disclosure are not necessarily limited thereto. For example, in an embodiment, the second sensor insulating layer 430 may include at least one of an acryl-based resin, methacryl-based resin, polyisoprene, vinyl-based resin, epoxy-based resin, urethane-based resin, cellulose-based resin, siloxane-based resin, polyimide-based resin, polyamide-based resin, and perylene-based resin.

A polarizing film 500 may be located on the sensor layer 400. In an embodiment, the polarizing film 500 is bonded to the sensor layer 400 by a light-transmissive adhesive layer 510. The polarizing film 500 may reduce external light reflection. As an example, when external light passes through the polarizing film 500, is reflected by the upper surface of the opposite electrode 230, and then passes through the polarizing film 500 again, since the light passes the polarizing film 500 twice, the phase of the external light may be changed. As a result, since the phase of reflected light becomes different from the phase of external light entering the polarizing film 500, destructive interference may occur. Consequently, since external light reflection is reduced, visibility may increase. The light-transmissive adhesive layer 510 and the polarizing film 500 may overlap a portion of the non-display area NDA as well as the display area DA.

The display apparatus DD according to an embodiment may not include the polarizing film 500. For example, the polarizing film 500 may be omitted and replaced by other elements. As an example, the polarizing film 500 may be omitted and external light reflection may be reduced by using a black matrix and color filters.

The window WD may be disposed on the polarizing film 500. The window WD may protect a display module DM from external impacts and provide an input surface and/or a display surface to users. In an embodiment, the window WD may be coupled to the polarizing film 500 through an optical transparent adhesive member.

In an embodiment, the window WD may be formed to have rigidity or flexibility by using glass or plastic. In addition, the window WD may have a single-layered structure or a multi-layered structure. In an embodiment in which the window WD has a multi-layered structure, the window WD may be formed through a successive process or an adhesion process that uses an adhesive layer.

FIG. 6 is a schematic cross-sectional view of a portion of the display apparatus DD according to an embodiment.

Referring to FIG. 6, the display apparatus DD according to an embodiment may include the substrate 100, a display layer DISL, the thin-film encapsulation layer 300, the sensor layer 400, the light-transmissive adhesive layer 510, the polarizing film 500, the window WD, a protective film 700, a cover panel 910, and a cover spacer 920. Descriptions of the elements already described above are omitted for economy of description.

As described above, the substrate 100 may include the first and second areas 1A and 2A facing different directions, and the third area 3A located therebetween. In an embodiment shown in FIG. 6, the substrate 100 may include a single layer in which the first, second, and third areas 1A, 2A, and 3A include the same material.

The first area 1A may include the display area DA. In an embodiment, the first area 1A may include a portion of the non-display area NDA outside the display area DA as well as the display area DA.

The display layer DISL, the thin-film encapsulation layer 300, the sensor layer 400, the light-transmissive adhesive layer 510, the polarizing film 500, and the window WD may be stacked in the first area 1A (e.g., in the z direction).

The display layer DISL may include the thin-film transistor TFT, the display element 200, and the insulating layers therebetween as shown in an embodiment of FIG. 5. The thin-film encapsulation layer 300 may be formed to cover the display layer DISL in the display area DA and the non-display area NDA in the first area 1A.

In an embodiment, a dam may be arranged in the non-display area NDA of the first area 1A. The dam may protrude from the upper surface of the substrate 100. The dam may be intended to control flowing of an organic material when forming the organic encapsulation layer of the thin-film encapsulation layer 300. The dam may overlap at least a portion of the thin-film encapsulation layer 300. The common power line 20 (see FIG. 3) may be arranged in the non-display area NDA. The common power line 20 is configured to supply the common voltage to the display area DA. The dam may overlap at least a portion of the common power line 20.

The polarizing film 500 may be disposed on the thin-film encapsulation layer 300 in the first area 1A. The polarizing film 500 may reduce reflectivity of light (e.g., external light) incident toward the display apparatus DD from the outside.

The light-transmissive adhesive layer 510 may be disposed between the polarizing film 500 and the thin-film encapsulation layer 300. In an embodiment, the light-transmissive adhesive layer 510 may be an optically clear adhesive (OCA). However, embodiments of the present disclosure are not necessarily limited thereto and an optically clear resin (OCR) may be applied. In addition, in an embodiment, the light-transmissive adhesive layer 510 may include a pressure sensitive adhesive (PSA). The PSA may include a polymer curable material. In an embodiment, the PSA may include an acryl-based or rubber-based adhesive, or an adhesive containing fine particles such as zirconia in the acryl-based or rubber-based adhesive.

In an embodiment, the display apparatus DD may not include the polarizing film 500 but may include a filter plate including a black matrix and color filters instead of the polarizing film 500.

The window WD may be disposed on the polarizing film 500. The window WD is configured to provide the display surface to users and may protect elements therebelow. As described above, the light-transmissive adhesive layer 510 may be disposed between the window WD and the polarizing film 500 (e.g., in the −z direction). The window WD may be arranged to correspond to the display area DA, the non-display area NDA of the first area 1A of the substrate 100, and the third area 3A that is bent.

A panel driver 800 may be arranged in the second area 2A. The panel driver 800 may be connected to the pad portion 30 of the substrate 100 and configured to supply data signals and scan signals to the gate line and the data line. The panel driver 800 may be spaced apart from the bending-protecting layer 600. In an embodiment, the panel driver 800 may be, for example, a driver integrated circuit (IC) and mounted on the pad portion 30 of the substrate 100. In this embodiment, the pad portion 30 may be directly electrically connected to the driver IC.

In an embodiment, a flexible circuit board 810 may be mounted on the pad portion 30 of the substrate 100, and the driver IC may be mounted on the flexible circuit board 810. The flexible circuit board 810 may be a chip-on-film (COF) or a flexible printed circuit FPC. A driver IC may be mounted on the flexible circuit board 810. The driver IC is configured to supply signals for allowing the plurality of display elements 200 in the display area DA to emit light. Both the panel driver 800 and the flexible circuit board 810 may be arranged in the second area 2A. However, various modifications may be made and embodiments of the present disclosure are not necessarily limited thereto.

The third area 3A of the substrate 100 is located between the first area 1A and the second area 2A and may be bent with a preset inner radius. The connection wiring CWL may be arranged in the third area 3A, and the bending-protecting layer 600 may be disposed on the connection wiring CWL (e.g., disposed directly thereon). The connection wiring CWL may be configured to transfer signals provided from the panel driver 800 and/or the flexible circuit board 810 to the display area DA of the first area 1A. The bending-protecting layer 600 may protect the connection wiring CWL and may be a stress neutralization layer.

For example, when a stack body is bent, there is a stress neutral plane in the stack body. In a comparative embodiment in which there is no bending-protecting layer 600 in the stack body, while the substrate 100 is bent, excessive tensile stress and the like may be applied to the connection wiring CWL located in the third area 3A. This is because the position of the connection wiring CWL may not correspond to the stress neutral plane. In contrast, when the bending-protecting layer 600 is disposed on the connection wiring CWL, and the thickness and the modulus of the bending-protecting layer 600 are adjusted, the position of the stress neutral plane of the stack body including all of the substrate 100, the connection wiring CWL, and the bending-protecting layer 600 may be adjusted. Accordingly, because the stress neutral plane is located near the connection wiring CWL through the bending-protecting layer 600, tensile stress applied to the connection wiring CWL may be reduced.

The bending-protecting layer 600 has an advantage of preventing cracks of the connection wiring CWL in the third area 3A. However, the bending-protecting layer 600 has a disadvantage of increasing a dead space DS of the display module DM due to the thickness thereof.

For example, since the bending-protecting layer 600 is formed at a preset thickness on the outside of the third area 3A that is bent, the dead space DS may increase by a thickness t4 thereof in a −x direction as shown in FIG. 6.

In view of the recent trend of reducing the non-display area NDA and increasing the display area DA, the bending-protecting layer 600 goes against the recent trend in that the bending-protecting layer 600 increases the dead space DS which is part of the non-display area NDA.

To reduce the dead space DS, the thickness t4 of the bending-protecting layer 600 may be formed relatively thin. However, in an embodiment in which the bending-protecting layer 600 is formed relatively thin, the stress neutral plane descends and possibility of cracks in the connection wiring CWL may increase. To prevent the descent of the stress neutral plane while making the thickness of the bending-protecting layer 600 relatively thin, the modulus of the bending-protecting layer 600 needs to be increased. However, a material of the bending-protecting layer 600 that has required specifications to increase the modulus of the bending-protecting layer 600 may be difficult to immediately applied in the manufacturing process.

Additionally, even though the bending-protecting layer is configured by using a material with an increased modulus, adhesive force is weakened when the modulus increases. Much time is taken to develop a material that increases the modulus and increases adhesive force. However, even if the material is developed, product unit price may increase due to a high-priced material.

In contrast, according to an embodiment of the present disclosure, since the thickness of the substrate 100 in the third area 3A is made relatively less than the thickness of the substrate 100 in the other regions, that is, the first area 1A or the second area 2A, the dead space DS may be reduced and the possibility of cracks in the connection wiring CWL in the third area 3A may be reduced without changing the thickness or material of the bending-protecting layer 600.

For example, in an embodiment in which a thickness t3 of the substrate 100 in the third area 3A is formed to be less than thicknesses t1 and t2 of the substrate 100 in the first area 1A or the second area 2A, which are the other regions of the substrate 100, the dead space DS is reduced as much as the thickness of the substrate 100 in the third area 3A is reduced.

In addition, as the thickness of the substrate 100 in the third area 3A is reduced, the stress neutral plane rises. However, in an embodiment in which the thickness of the substrate 100 in the third area 3A is reduced, the modulus of the bending-protecting layer 600 is reduced without a change in the thickness t4 of the bending-protecting layer 600. The reduction in the modulus of the bending-protecting layer 600 induces the descent of the stress neutral plane that ascends as the thickness of the substrate 100 in the third area 3A is reduced. Accordingly, the stress neutral plane is located between the substrate 100 and the connection wiring CWL, and the possibility of cracks in the connection wiring CWL may be reduced.

In an embodiment, the inner radius of the third area 3A that is bent may be in a range of about 0.17 mm to about 0.19 mm, and the thickness t4 of the bending-protecting layer 600 may be in a range of about 0.04 mm to about 0.1 mm.

The substrate 100 has a first surface and a second surface located opposite the first surface. The display elements 200 may be located on the first surface of the substrate 100. The protective film 700 may be located on the second surface of the substrate 100 which is the surface on which images are not displayed. The protective film 700 may be attached to the second surface of the substrate 100 and may protect the display apparatus DD. In an embodiment, the protective film 700 may be attached to the other surface of the substrate 100 by using an adhesive. The protective film 700 may be located in the first area 1A and the second area 2A of the substrate 100, and may not be located in the third area 3A.

The cover panel 910 may be disposed on the backside of the protective film 700. In an embodiment, an adhesive layer may be disposed between the protective film 700 and the cover panel 910. The cover panel 910 may protect the display module DM from external impacts and the like.

The cover panel 910 alleviates external impacts and may include a cushion layer including an elastically transformable material. As an example, in an embodiment the cover panel 910 may include a single-layered or multi-layered cushion layer including at least one material among thermoplastic elastomer, polystyrene, polyolefin, polyurethane thermoplastic elastomers, polyamides, synthetic rubbers, polydimethylsiloxane, polybutadiene, polyisobutylene, [poly(styrene-butadiene styrene)], polyurethane, polychloroprene, polyethylene, silicone, and a combination thereof. In addition, the cover panel 910 may include a suitable material within a range that does not affect image display of the display panel DP among materials having elastic force.

In addition, in an embodiment the cover panel 910 may further include a high-strength plate (e.g., a metal plate), graphite, a copper plate, and/or a heat dissipation plate for stably supporting the display panel DP on the rear surface of the display panel DP.

As an example, the cover panel 910 may include an embossing layer, an absorption layer, and a support member sequentially disposed on the rear surface of the display panel DP. However, the structure of the cover panel 910 is not necessarily limited thereto and the cover panel 910 may further include additional elements having various functions.

In addition, mutual positions (e.g., a stacking order) between respective elements constituting the cover panel 910 may be variously changed. As an example, in an embodiment, though the embossing layer, the absorption layer, and the support member are sequentially disposed on the rear surface of the display panel DP, the support member may be disposed first on the rear surface of the display panel DP. In an embodiment, the embossing layer and/or the absorption layer may be disposed first on the rear surface of the support member.

The embossing layer may include a plurality of embossing patterns alleviating and dispersing external impacts and the like, and include a single layer or a multi-layer. The absorbent layer is filled with air or a dispersible material or a sound-absorbing material to absorb external impact, and may include a single layer or a multi-layer. In an embodiment, the embossing layer and the absorption layer may be separately formed and coupled to each other by using an adhesive. However, embodiments of the present disclosure are not necessarily limited thereto and the embossing layer and the absorption layer may be formed as a single layer.

The support member may include a material having high strength and/or high ductility to secure or increase mechanical strength of the display apparatus DD. As an example, the support member may be a metal plate including at least one type of metal or alloy. In addition, the support member may have sufficient strength by having a thickness in the range of about 10 μm to hundreds of μm. Accordingly, the mechanical strength of the display apparatus DD may be secured or increased.

The support member may be configured to stably support other elements of the cover panel 910 thereon, for example, the embossing layer, the absorption layer, a reinforcing member, the display module DM, and/or the window WD, and the like. Accordingly, the mechanical strength of the display apparatus DD may be secured or increased.

In an embodiment, the support member may be integrally configured with the heat dissipation plate. As an example, the support member may include a material capable of dissipating heat generated from heat generating members disposed in the display apparatus DD to provide a heat dissipation function, and simultaneously, stably support the rear surface of the display module DM. In this embodiment, the support member may include a material having high thermal conductivity to exhibit high heat dissipation characteristics. As an example, the support member may include an organic material having high thermal conductivity, such as carbon (e.g., graphite), or a metal. In addition, in an embodiment a plurality of through holes may be formed in the support member to secure high heat dissipation characteristics. Since the support member includes the heat dissipation plate, heat emitted from the heat generating members adjacent to the support member may be easily dissipated while the display apparatus DD is driven. Accordingly, even though the display apparatus DD is continuously driven, driving stability may be secured.

In an embodiment, the support member is not necessarily limited to being integrally formed with the heat dissipation plate. As an example, in an embodiment, the cover panel 910 may include a heat dissipation plate configured separately from the support member. For example, the cover panel 910 may include the heat dissipation plate in addition to the support member. In this embodiment, the support member may be designed with more emphasis on mechanical strength and/or flexibility of the display apparatus DD.

The cover spacer 920 may be configured to control the degree of bending of the display panel DP by maintaining a uniform interval between the cover panel 910 and one region of the display panel DP corresponding to the second area 2A while the display panel DP is bent. In addition, the cover spacer 920 may be configured to support one region of the display panel DP corresponding to the second area 2A when the first area 1A faces the second area 2A while the display panel DP is bent. In an embodiment, the cover spacer 920 may include the same material as a material of the cover panel 910. However, embodiments of the present disclosure are not necessarily limited thereto. As an example, the cover spacer 920 may include an elastic material suitable for design conditions of the display panel DP.

FIG. 7 is a schematic cross-sectional view of the display apparatus DD according to an embodiment. The embodiment shown in FIG. 7 is different from the embodiment shown in FIG. 6 in the configuration of the substrate. Hereinafter, the configuration of a substrate 100′ is mainly described.

Referring to FIG. 7, the substrate 100′ may include a base layer 101 and a second base layer 102 disposed on the base layer 101. In an embodiment, the first base layer 101 may include the same material as a material of the second base layer 102. However, embodiments of the present disclosure are not necessarily limited thereto and the first base layer 101 may include a material different from a material of the second base layer 102.

A second barrier layer 103 may be disposed between the first base layer 101 and the second base layer 102 (e.g., in the z direction). In an embodiment, the first barrier layer 104 may include the same material as a material of the second barrier layer 103. In addition, the first barrier layer 104 may include a material different from a material of the second barrier layer 103. The second barrier layer 103 may include a single layer or a multi-layer including the inorganic insulating material. In some embodiments, the first barrier layer 104 may be omitted.

A thickness t3′ of the first base layer 101 of the substrate 100′ in the third area 3A may be less than a thickness t1′ of the first base layer 101 in the first area 1A or a thickness t2′ of the first base layer 101 in the second area 2A. For example, a portion of the first base layer 101 in the third area 3A that is bent may be removed, and thus, the thickness of the first base layer 101 in the third area 3A may become less than the thickness t1 of the first base layer 101 in the first area 1A or the second area 2A.

Accordingly, as described with reference to FIG. 6, the possibility of cracks in the connection wiring CWL in the third area 3A may be reduced and the dead space DS may be reduced without a change in the thickness or material of the bending-protecting layer 600.

In an embodiment in which the thickness t3′ of the substrate 100′ in the third area 3A is less than thicknesses t1′ and t2′ of the substrate 100′ in the first area 1A or the second area 2A, which are the other regions of the substrate 100′, the dead space DS is reduced as much as the thickness of the substrate 100′ in the third area 3A is reduced.

In addition, as the thickness t3′ of the substrate 100′ in the third area 3A is reduced, the stress neutral plane rises. However, in an embodiment in which the thickness t3′ of the substrate 100′ in the third area 3A is reduced, the modulus of the bending-protecting layer 600 is reduced without a change in the thickness t4 of the bending-protecting layer 600. The reduction in the modulus of the bending-protecting layer 600 induces the descent of the stress neutral plane that ascends as the thickness t3′ of the substrate 100′ in the third area 3A is reduced. Accordingly, the stress neutral plane is located between the substrate 100′ and the connection wiring CWL, and the possibility of cracks in the connection wiring CWL may be reduced.

As an example, assuming that the thickness t3′ of the first base layer 101 in the third area 3A is x, and the modulus of the bending-protecting layer 600 is y, a relational equation of y=62x-70 may be satisfied. y may be a minimum value of the modulus of the bending-protecting layer 600, and a maximum value of the modulus of the bending-protecting layer 600 may be 1.4*y.

In an embodiment in which the modulus y of the bending-protecting layer 600 is less than 62x-70, the stress neutral plane descends and the possibility that cracks occur in the connection wiring CWL increases. In an embodiment in which the modulus y of the bending-protecting layer 600 is greater than 1.4*(62x-70), the bending is difficult and adhesive force is weakened.

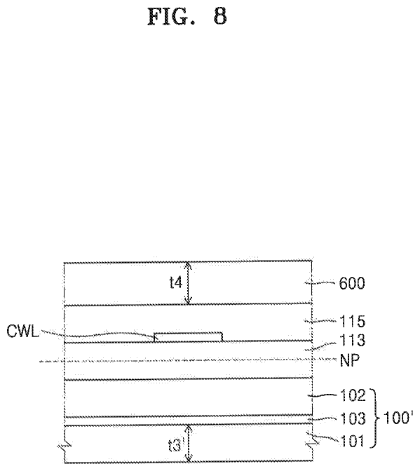

FIG. 8 is a schematic cross-sectional view of a third area of the display apparatus DD shown in FIG. 7.

Referring to FIG. 8, in an embodiment, the first planarization layer 113, the second planarization layer 115, the bending-protecting layer 600 may be stacked in the third area 3A of the substrate 100 of the display apparatus DD, and the connection wiring CWL may be disposed between the first planarization layer 113 and the second planarization layer 115.

Since the thickness t3′ of the first base layer 101 in the third area 3A that is bent is less than the thicknesses t1′ and t2′ of the first base layer 101 in the first and second areas 1A and 2A, the stress neutral plane in the third area 3A may be located between the second base layer 102 and the connection wiring CWL without a change in the thickness t4 of the bending-protecting layer 600. Accordingly, the dead space DS in a direction from the first area 1A to the third area 3A may be reduced, and the possibility of cracks in the connection wiring CWL in the third area 3A may be reduced.

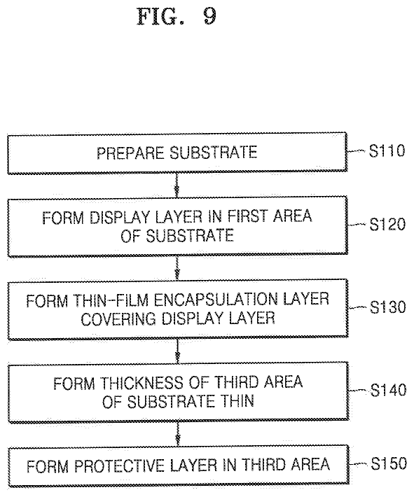

FIG. 9 is a schematic flowchart showing a method of manufacturing the display apparatus DD according to an embodiment.

Referring to FIG. 9, the substrate 100 may be prepared in block S110. The substrate 100 includes the first area 1A, the second area 2A spaced apart from the first area 1A, and the third area 3A located between the first area 1A and the second area 2A. In an embodiment, the substrate 100 may include a single layer in which the first, second, and third areas 1A, 2A, and 3A include the same material. In an embodiment, the substrate 100 may include a stack of the first base layer 101, the second base layer 102, and the barrier layer 103 therebetween. However, embodiments of the present disclosure are not necessarily limited thereto and the substrate 100 may include a stack structure of a base layer of three or more layers.

The display layer DISL may then be formed in the first area 1A of the substrate 100 in block S120. For example, the display layer DISL may be formed solely in the first area 1A of the substrate. The display layer DISL may include the thin-film transistor TFT, the display element 200, and the insulating layers therebetween over the substrate 100.

The thin-film encapsulation layer 300 may then be formed to cover the display layer DISL in block S130. The thin-film encapsulation layer 300 may be formed to cover the display layer DISL in the display area DA and the non-display area NDA in the first area 1A.

The rear surface of the substrate 100 in the third area 3A may then be formed to a preset thickness in block S140. A portion of the substrate 100 may then be removed to a preset thickness from the second surface facing the first surface of the substrate 100 on which the display layer DISL is formed, such as the second surface of the substrate 100 corresponding to the third area 3A between the first area 1A and the second area 2A. Before the substrate 100 is bent in the third area 3A, the rear surface of the substrate 100 in the third area 3A may be removed to a preset thickness. In an embodiment, the removing of the rear surface of the substrate 100 may be performed by a laser beam or plasma process. However, embodiments of the present disclosure are not necessarily limited thereto.

In an embodiment, after the forming of the thin-film encapsulation layer in block S130 and before the reducing of the thickness of the third area 3A, a pad portion 30 may be formed in the second area 2A and connection wirings CWL may be formed in the third area 3A. The connection wirings CWL may electrically connect the display element 200 to the pad portion 30.

The bending-protecting layer 600 may then be formed in the third area 3A, and the third area 3A may be bent. The bending-protecting layer 600 may be solely disposed outside of the first area 1A and the second area 1A.

According to an embodiment, cracks in the bent area may be prevented and the dead space due to the bent area may be reduced.

It should be understood that embodiments of the present disclosure described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus comprising:
a substrate including a first area, a second area, and a third area, the first area facing a first direction, the second area extending from the first area and facing a second direction different from the first direction, and the third area disposed between the first area and the second area;
a display element arranged in the first area; and
a bending-protecting layer arranged in the third area, the bending-protecting layer is disposed outside of the first area;
wherein a thickness of the substrate in the third area is less than a thickness of the substrate in the first area.

2. The display apparatus of claim 1, wherein an inner radius of the third area is in a range of about 0.17 mm to about 0.19 mm.

3. The display apparatus of claim 1, wherein a thickness of the bending-protecting layer is in a range of about 0.04 mm to about 0.1 mm.

4. The display apparatus of claim 1, further comprising:
a pad portion arranged in the second area; and
a connection wiring arranged in the third area, the connection wiring electrically connecting the display element to the pad portion.

5. The display apparatus of claim 4, wherein a stress neutral plane in the third area is arranged between a surface of the substrate and the connection wiring.

6. The display apparatus of claim 1, wherein the substrate includes a first base layer and a second base layer stacked on the first base layer.

7. The display apparatus of claim 6, wherein a thickness of the first base layer in the third area is less than a thickness of the first base layer in the first area.

8. The display apparatus of claim 7, wherein the thickness of the first base layer in the third area is less than a thickness of the first base layer in the second area.

9. The display apparatus of claim 6, wherein, a relational equation between a modulus of the bending-protecting layer and a thickness of the first base layer in the third area is equal to y=62x-70, wherein x is the thickness of the first base layer in the third area and y is the modulus of the bending-protecting layer.

10. The display apparatus of claim 9, wherein a modulus of the bending-protecting layer is greater than 62x-70 and less than 1.4*(62x-70).

11. The display apparatus of claim 6, further comprising a barrier layer disposed between the first base layer and the second base layer.

12. A method of manufacturing a display apparatus, the method comprising:
preparing a substrate including a first area, a second area, and a third area, the second area is spaced apart from the first area, and the third area is disposed between the first area and the second area;
forming a display element in the first area;
forming a thin-film encapsulation layer covering the display element:
reducing a thickness of the substrate in the third area to be less than a thickness of the substrate in the first area;
forming a bending-protecting layer in the third area, the bending-protecting layer is disposed outside of the first area; and
bending the third area so that the first area faces a first direction that is different from a second direction that the second area faces.

13. The method of claim 12, wherein the bending of the third area includes bending the third area such that an inner radius of the third area is in a range of about 0.17 mm to about 0.19 mm.

14. The method of claim 12, wherein a thickness of the bending-protecting layer is in a range of about 0.04 mm to about 0.1 mm.

15. The method of claim 12, further comprising, after the forming of the thin-film encapsulation layer and before the reducing of the thickness of the third area, forming a pad portion in the second area and forming a connection wiring in the third area, wherein the connection wiring electrically connects the display element to the pad portion.

16. The method of claim 15, wherein the reducing of the thickness of the third area includes reducing the thickness of the third area such that a stress neutral plane in the third area is formed between a surface of the substrate and the connection wiring.

17. The method of claim 12, wherein the reducing of the thickness of the third area includes etching the substrate by using a laser beam or plasma.

18. The method of claim 12, wherein the substrate is formed by stacking a first base layer and a second base layer on the first base layer.

19. The method of claim 18, wherein a thickness of the first base layer in the third area is less than a thickness of the first base layer in the first area.

20. The method of claim 19, wherein the thickness of the first base layer in the third area is less than a thickness of the first base layer in the second area.

21. The method of claim 18, wherein, a relational equation between a modulus of the bending-protecting layer and a thickness of the first base layer in the third area is equal to y=62x-70, wherein x is the thickness of the first base layer in the third area and y is the modulus of the bending-protecting layer.

22. The method of claim 21, wherein a modulus of the bending-protecting layer is greater than 62x-70 and less than 1.4*(62x-70).

23. The method of claim 18, further comprising forming a barrier layer between the first base layer and the second base layer.
